(19) United States
(12) Patent Application Publication
(10) Pub. No.: US 2026/0165189 A1
(43) Pub. Date: Jun. 11, 2026

(54) SEMICONDUCTOR PACKAGE

(71) Applicant: Samsung Electronics Co., Ltd., Suwon-si (KR)

(72) Inventors: Won Ho CHOI, Suwon-si (KR); Ji Soo KIM, Suwon-si (KR); Hyun Ho KIM, Suwon-si (KR); Hyung Jun PARK, Suwon-si (KR); Sang-Hyuck OH, Suwon-si (KR); Hong Seo HEO, Suwon-si (KR)

(21) Appl. No.: 19/291,099

(22) Filed: Aug. 5, 2025

(30) Foreign Application Priority Data
Dec. 10, 2024 (KR) 10-2024-0182535

(51) Int. Cl. H01L 23/31; H01L 23/00; H01L 23/29; H01L 23/498; H01L 25/16

(52) U.S. Cl. CPC H10W 74/121; H10W 74/134; H10W 74/40; H10W 90/00; H10W 90/401; H10W 90/701; H10W 90/724

(57) ABSTRACT

A semiconductor package includes a first redistribution substrate including an upper surface and a lower surface, a semiconductor chip mounted on the upper surface of the first redistribution substrate, and including an upper surface and a lower surface, a protective film structure disposed on the upper surface of the semiconductor chip, a silicon capacitor disposed on the lower surface of the first redistribution substrate, an encapsulant covering the upper surface of the first redistribution substrate, a side surface of the semiconductor chip, and the protective film structure, and a plurality of solder balls disposed on the lower surface of the first redistribution substrate. The plurality of solder balls are arranged to surround the silicon capacitor when viewed in a plan view. The lower surface of the semiconductor chip is adjacent to the upper surface of the first redistribution substrate.

### CROSS-REFERENCE TO RELATED APPLICATION

This application claims priority from Korean Patent Application No. 10-2024-0182535 filed on Dec. 10, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor package.

### 2. Description of the Related Art

In recent years, a wafer level-chip size package (WL-CSP), which enables miniaturization, high functionality, and high performance of semiconductor devices, has been put to practical use. In the WL-CSP, a packaging process is completed in a wafer state, and each chip size cut by dicing becomes a package size.

There is a likelihood that a crack risk occurs on the top of the semiconductor chip while going through a series of processes, and therefore, a method capable of mitigating the crack risk is required.

### SUMMARY

Aspects of the present disclosure provide a semiconductor package that may improve the performance and reliability of products.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a semiconductor package includes a first redistribution substrate which includes an upper surface and a lower surface that are opposite to each other in a vertical direction perpendicular to the upper surface, a semiconductor chip which is mounted on the upper surface of the first redistribution substrate, and includes an upper surface and a lower surface that are opposite to each other in the vertical direction, a protective film structure disposed on the upper surface of the semiconductor chip, a silicon capacitor disposed on the lower surface of the first redistribution substrate, an encapsulant which covers the upper surface of the first redistribution substrate, a side surface of the semiconductor chip, and the protective film structure, and a plurality of solder balls disposed on the lower surface of the first redistribution substrate. The plurality of solder balls are arranged to surround the silicon capacitor when viewed in a plan view. The lower surface of the semiconductor chip is adjacent to the upper surface of the first redistribution substrate.

According to an aspect of the present disclosure, a semiconductor package includes a first redistribution substrate which includes an upper surface and a lower surface that are opposite to each other in a vertical direction perpendicular to the upper surface, a semiconductor chip which is mounted on the upper surface of the first redistribution substrate, and includes an upper surface and a lower surface that are opposite to each other in the vertical direction, a protective film structure disposed on the upper surface of the semiconductor chip, a plurality of first connecting members which are disposed in a space between the upper surface of the first redistribution substrate and the lower surface of the semiconductor chip, and connect the first redistribution substrate to the semiconductor chip, a second redistribution substrate disposed on the upper surface of the semiconductor chip, an encapsulant which is disposed in a space between the first redistribution substrate and the second redistribution substrate, and covers the upper surface of the semiconductor chip and the upper surface of the first redistribution substrate, a plurality of metal pillars penetrating the encapsulant and connecting the first redistribution substrate to the second redistribution substrate, and a plurality of solder balls which are disposed on the lower surface of the first redistribution substrate.

According to an aspect of the present disclosure, a semiconductor package includes a first redistribution substrate which includes an upper surface and a lower surface that are opposite to each other in a vertical direction perpendicular to the upper surface, a semiconductor chip which is mounted on the upper surface of the first redistribution substrate, and includes an upper surface and a lower surface that are opposite to each other in the vertical direction, a protective film structure disposed on the upper surface of the semiconductor chip, a silicon capacitor which is disposed on the lower surface of the first redistribution substrate and has a square shape when viewed in a plan view, a plurality of connecting members disposed in a space between the silicon capacitor and the first redistribution substrate, an underfill which covers the plurality of connecting members disposed in the space between the silicon capacitor and the first redistribution substrate, and a plurality of solder balls which are arranged to surround the silicon capacitor when viewed in the plan view, and are disposed on the lower surface of the first redistribution substrate. The upper surface of the semiconductor chip includes surface irregularities that are distributed in a non-uniform manner. A thickness, in the vertical direction, between an upper surface of the protective film structure and a topmost level of the upper surface of the semiconductor chip has a value in a range of 2% to 10%, inclusive, of a thickness, in the vertical direction, between the lower surface of the semiconductor chip to the topmost level of the upper surface of the semiconductor chip. According to an aspect of the present disclosure, a semiconductor package includes a first redistribution substrate which includes an upper surface and a lower surface that are opposite to each other in a vertical direction perpendicular to the upper surface, a semiconductor chip which is mounted on the upper surface of the first redistribution substrate, and includes an upper surface and a lower surface that are opposite to each other in the vertical direction, a protective film structure disposed on the upper surface of the semiconductor chip, a silicon capacitor which is disposed on the lower surface of the first redistribution substrate and has a square shape when viewed in a plan view, a plurality of connecting members disposed in a space between the silicon capacitor and the first redistribution substrate, an underfill which covers the plurality of connecting members disposed in the space between the silicon capacitor and the first redistribution substrate, and a plurality of solder balls which are arranged to surround the silicon capacitor when viewed in the plan view, and are disposed on the lower surface of the first redistribution substrate. The upper surface of the semiconductor chip includes surface irregularities that are distributed in a non-uniform manner. A thickness, in the vertical direction, between an upper surface of the protective film structure and a topmost level of the upper surface of the semiconductor chip has a value in a range of 2% to 10%, inclusive, of a thickness, in the vertical direction, between the lower surface of the semiconductor chip to the topmost level of the upper surface of the semiconductor chip.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an example plan view for explaining a semiconductor package according to some embodiments of the present disclosure.

FIG. 2 is an example cross-sectional view taken along line A-A of FIG. 1 according to some embodiments of the present disclosure.

FIG. 3 is an enlarged view of a region P of FIG. 2 for explaining the semiconductor package according to some embodiments of the present disclosure.

FIG. 4 is an example cross-sectional view taken along line A-A of FIG. 1 according to another embodiment of the present disclosure.

FIG. 5 is an example cross-sectional view taken along line A-A of FIG. 1 according to another embodiment of the present disclosure.

FIG. 6 is an example cross-sectional view taken along line A-A in FIG. 1 according to another embodiment of the present disclosure.

FIGS. 7 to 17 are diagrams for explaining the manufacturing process of the semiconductor package having the cross-section of FIG. 2.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

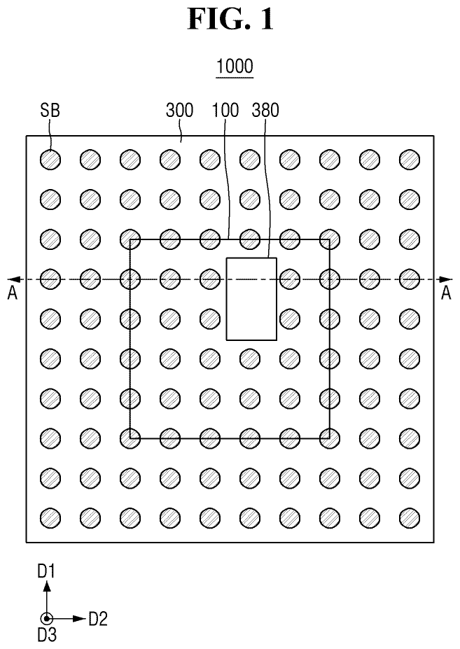

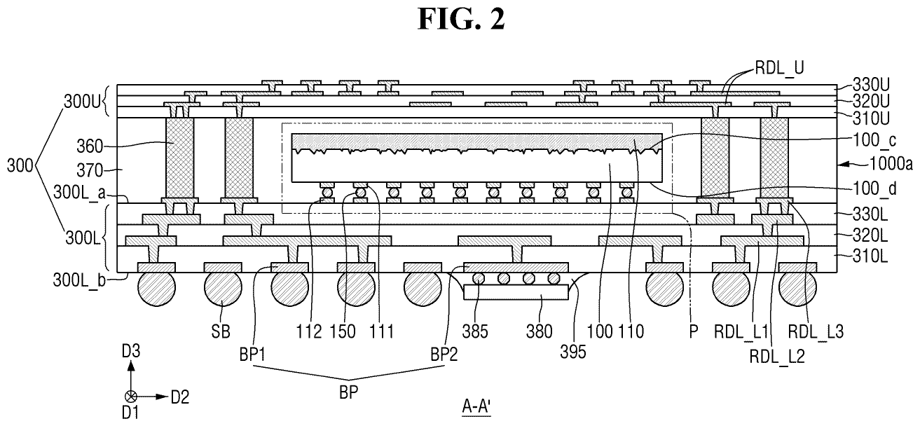

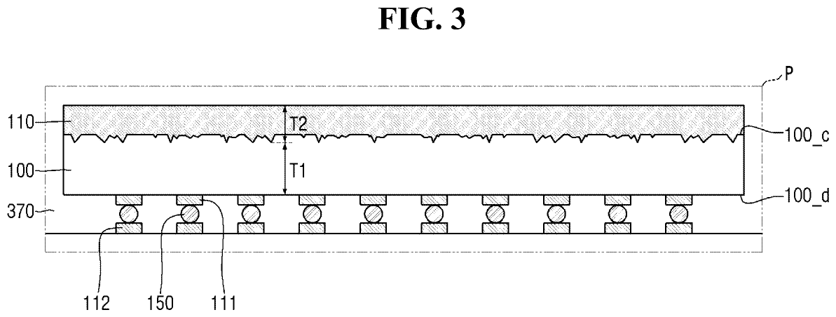

FIG. 1 is an example plan view for explaining a semiconductor package according to some embodiments of the present disclosure. FIG. 2 is an example cross-sectional view taken along line A-A of FIG. 1 according to some embodiments of the present disclosure. FIG. 3 is an enlarged view of a region P of FIG. 2 for explaining the semiconductor package according to some embodiments of the present disclosure.

Referring to FIGS. 1 to 3, a semiconductor package 1000 according to some embodiments of the present disclosure may further include a redistribution substrate 300, a semiconductor chip 100, a plurality of ball pads BP, a silicon capacitor 380, a plurality of first connecting members 385, an underfill 395, a plurality of solder balls SB, a plurality of metal pillars 360, a molding film 370, a plurality of first chip pads 111, a plurality of second chip pads 112, and a plurality of second connecting members 150.

The redistribution substrate 300 may include a lower redistribution substrate 300L and an upper redistribution substrate 300U. The lower redistribution substrate 300L may be disposed under the semiconductor chip 100. The upper redistribution substrate 300U may be disposed above the semiconductor chip 100.

For example, the lower redistribution substrate 300L may include a first side 300L_a (i.e., an upper surface) and a second side 300L_b (i.e., a lower surface) that are opposite to each other in a vertical direction perpendicular to the first side 300L_a. The first side 300L_a and the second side 300L_b may be opposite to each other. The upper redistribution substrate 300U and the semiconductor chip 100 may be disposed on the first side 300L_a of the lower redistribution substrate. The silicon capacitor 380 may be disposed on the second side 300L_b of the lower redistribution substrate. The plurality of solder balls SB may be disposed on the second side 300L_b of the lower redistribution substrate. The first side 300L_a may face (i.e., may be adjacent to) the semiconductor chip 100. The second side 300L_b may face the solder balls SB. The second side 300L_b may face the silicon capacitor 380.

The plurality of solder balls SB may be disposed around the silicon capacitor 380. The plurality of solder balls SB may surround the silicon capacitor 380 when viewed in a plan view.

In this specification, a first direction D1, a second direction D2, and a third direction D3 may be different directions from each other. For example, the first direction D1, the second direction D2, and the third direction D3 may intersect each other, but are not limited thereto. The third direction D3 may be a thickness direction of the redistribution substrate 300. For example, the third direction D3 may correspond to the vertical direction perpendicular to the first side 300L_a. The plurality of solder balls SB are disposed on the second side 300L_b of the lower redistribution substrate in a plane in which the first direction D1 and the second direction D2 extend. For example, the first direction D1 and the second direction D2 may be parallel to the first side 300L_a.

The lower redistribution substrate 300L may include first to third lower insulating layers 310L, 320L, and 330L. The first to third lower redistribution patterns RDL_L1, RDL_L2, and RDL_L3 and the plurality of ball pads BP may be disposed inside the first to third lower insulating layers 310L, 320L, and 330L.

As an example, the first lower insulating layer 310L may wrap the ball pads BP. Each ball pad of the ball pads BP may be exposed at one side (e.g., a lower surface) of the first lower insulating layer 310L. For example, each ball pad of the ball pads BP may be exposed at a second side 300L_b of the lower redistribution substrate.

The first lower insulating layer 310L may wrap a via portion of the first lower redistribution pattern RDL_L1. The second lower insulating layer 320L may wrap a wiring portion of the first lower redistribution pattern RDL_L1. The second lower insulating layer 320L may wrap a via portion of the second lower redistribution pattern RDL_L2. The third lower insulating layer 330L may wrap a wiring portion of the second lower redistribution pattern RDL_L2. The third lower insulating layer 330L may wrap a via portion of the third lower redistribution pattern RDL_L3. However, the technical idea of the present disclosure is not limited thereto.

Each of the first to third lower insulating layers 310L, 320L, and 330L may be made up of a photoimageable dielectric. For example, the first to third lower insulating layers 310L, 320L, and 330L may include a photosensitive polymer. The photosensitive polymer may be formed of at least one of, for example, photosensitive polyimide, polybenzoxazole, a phenol-based polymer, and a benzocyclobutene-based polymer. As another example, the first to third lower insulating layers 310L, 320L, and 330L may be formed of a silicon oxide film, a silicon nitride film, or a silicon oxynitride film.

Each of the first to third lower redistribution patterns RDL_L1, RDL_L2, and RDL_L3 may include a conductive material. For example, the first to third lower redistribution patterns RDL_L1, RDL_L2, and RDL_L3 may include, but not limited to, copper (Cu). In an embodiment, each of the first to third lower redistribution patterns RDL_L1, RDL_L2, and RDL_L3 may include a diffusion barrier to prevent Cu diffusion.

In some embodiments, the lower redistribution substrate 300L may include an organic material. For example, the lower redistribution substrate 300L may include a pre-preg, which is short for pre-impregnated composite fiber. The pre-preg is a composite fiber in which a reinforcing fiber such as a carbon fiber, a glass fiber, and an aramid fiber is pre-impregnated with a thermosetting polymer binder (e.g., epoxy resin) or a thermoplastic resin. In some embodiments, the lower redistribution substrate 300L may include a copper clad laminate (CCL). For example, the lower redistribution substrate 300L may have a structure in which a copper foil is laminated on a single side or both sides of a heat-cured pre-preg (e.g., a C-stage pre-preg).

The plurality of ball pads BP may be provided in the lower redistribution substrate 300L. The plurality of ball pads BP may be provided in the first lower insulating layer 310L. The plurality of ball pads BP may be exposed at the second side 300L_b of the lower redistribution substrate. A bottom end of each of the plurality of ball pads BP may be disposed at the same plane as the second side 300L_b of the lower redistribution substrate. The plurality of ball pads BP may include a first ball pad BP1 and a second ball pad BP2. In some embodiments, the first ball pad BP1 may be connected to the solder ball SB. The second ball pad BP2 may be connected to the silicon capacitors 380. However, the technical idea of the present disclosure is not limited thereto.

Each of the plurality of ball pads BP may include a conductive material. For example, the plurality of ball pads BP may include, but not limited to, copper (Cu). For example, the pads may include, but not limited to, copper (Cu). In an embodiment, the pads for the plurality of first connecting members 385 and the ball pads BP may include diffusion barriers to prevent Cu diffusion.

The plurality of solder balls SB may be provided on the first ball pad BP1. The solder balls SB may be connected to the first ball pad BP1. Although each of the plurality of solder balls SB is shown to have a ball shape, the technical idea of the present disclosure is not limited thereto. Each of the plurality of solder balls SB may have various shapes, such as a land, a ball, a pin, and a pillar. The number, interval, or placement of the plurality of solder balls SB are not limited to those shown in the drawings, and may vary depending on the design. Each of the plurality of solder balls SB may be, but not limited to, a solder bump including a low-melting point metal, for example, tin (Sn) or a tin (Sn) alloy.

The silicon capacitor 380 may be provided on the second side 300L_b of the lower redistribution substrate. The silicon capacitor 380 may be connected to the second ball pad BP2 exposed at the second side 300L_b of the lower redistribution substrate using the plurality of first connecting members 385. The silicon capacitor 380 may include silicon (Si). As an example, the silicon capacitor 380 may be, but not limited to, a silicon (Si) capacitor. Although one silicon capacitor 380 is shown in the present specification, the embodiment is not limited thereto. The placement and number of the silicon capacitors 380 may vary depending on the design.

Although not shown, the semiconductor package 1000 according to some embodiments may further include a multi-layer ceramic capacitor (MLCC). The multi-layer ceramic capacitor may be disposed at a position adjacent to the silicon capacitor 380, or may be disposed at a position spaced apart from the silicon capacitor 380.

The plurality of first connecting members 385 may be provided between the second ball pad BP2 exposed at the second side 300L_b of the lower redistribution substrate and the silicon capacitor 380. The plurality of first connecting members 385 may connect the silicon capacitor 380 to the second ball pad BP2 exposed at the second side 300L_b of the lower redistribution substrate. The semiconductor chip 100 and the silicon capacitor 380 may be electrically connected through the plurality of first connecting members 385.

The plurality of first connecting members 385 may be, but not limited to, solder bumps including a low-melting point metal, for example, tin (Sn) or a tin (Sn) alloy. The plurality of first connecting members 385 may have various shapes, such as a land, a ball, a pin, and a pillar. The plurality of first connecting members 385 may be formed of a single layer or multiple layers. When the plurality of first connecting members 385 are formed of a single layer, the plurality of first connecting members 385 may include tin-silver (Sn—Ag) solder or copper (Cu) as an example. When the plurality of first connecting members 385 are formed as multiple layers, the plurality of first connecting members 385 may include copper (Cu) filler and solder as an example. The number, intervals, or placement of the plurality of first connecting members 385 are not limited to those shown in the drawings and may be various depending on the design.

The underfill 395 may be formed between the lower redistribution substrate 300L and the silicon capacitor 380. The underfill 395 may fill a space between the lower redistribution substrate 300L and the silicon capacitor 380. The underfill 395 may wrap the plurality of first connecting members 385.

The semiconductor chip 100 may be mounted on the first side 300L_a of the lower redistribution substrate. The semiconductor chip 100 may be disposed in a center region of the lower redistribution substrate 300L in a plan view. In an embodiment, the semiconductor chip 100 may be a semiconductor die which is singulated from a wafer and may have no protective packaging. In an embodiment, the semiconductor chip 100 may be a silicon die used in wafer-level packaging such as the WL-CSP.

The semiconductor chip 100 may include a third side 100_c (i.e., an upper surface) and a fourth side 100_d (i.e., a lower surface) that are opposite to each other in the third direction D3. The third side 100_c and the fourth side 100_d of the semiconductor chip may be opposite to each other in the third direction D3. The third side 100_c of the semiconductor chip may face (i.e., may be adjacent to) the upper redistribution substrate 300U to be described below. The fourth side 100_d of the semiconductor chip may face (i.e., may be adjacent to) the solder ball SB. The fourth side 100_d of the semiconductor chip may face (i.e., may be adjacent to) the silicon capacitor 380.

The third side 100_c of the semiconductor chip has an uneven surface. For example, the third side 100_c of the semiconductor chip may include an unevenness disposed irregularly. By the unevenness, the contact force with the protective film structure 110 disposed on the upper surface of the unevenness may be improved. The upper surface of the semiconductor chip may include surface irregularities that are distributed in a non-uniform manner.

A protective film structure 110 may be disposed on the third side 100_c of the semiconductor chip. For example, the protective film structure 110 may cover the third side 100_c of the semiconductor chip. The protective film structure 110 may be formed to cover the unevenness of the third side 100_c of the semiconductor chip. For example, no space may be formed between the protective film structure 110 and the semiconductor chip 100. In an embodiment, the protective film structure 110 may contact the third side 100_c of the semiconductor chip. The term “contact,” as used herein, refers to a direct connection (i.e., physical touching) unless the context indicates otherwise. In an embodiment, the protective film structure 110 may include, for example, copper (Cu) or gold (Au). The semiconductor chip 100 may be unpackaged, and thus the back side of a silicon substrate of the semiconductor chip 100 may contact the protective film structure 110. The back side of the silicon substrate may correspond to the third side 100_c of the semiconductor chip.

A thickness T2 in the third direction D3 from the bottom to the top of the protective film structure 110 is smaller than a thickness T1 in the third direction D3 from the fourth side 100_d to the bottom of the third side 100_c of the semiconductor chip. The bottom of the protective film structure 110 may refer to the same point as the bottom of the third side 100_c of the semiconductor chip.

Although the thickness of the protective film structure 110 is expressed as being relatively large for convenience of explanation in FIG. 3, the thickness T2 of the protective film structure 110 in the third direction D3 from the bottom to the top may be about 2% or more and 10% or less of the thickness T1 in the third direction D3 from the fourth side 100_d of the semiconductor chip to the bottom (i.e., a bottommost level) of the third side 100_c. The protective film structure 110 having the thickness may effectively cover the uneven surface of the third side 100_c of the semiconductor chip 100. Through this, the crack risk of the semiconductor chip may be reduced, and a semiconductor package with improved reliability may be provided. For example, when the thickness T1 in the third direction D3 from the fourth side 100_d of the semiconductor chip to the bottom of the third side 100_c is about 120 μm, the thickness T2 in the third direction D3 from the bottom to the top of the protective film structure 110 may be about 3 μm or more and 10 μm or less. The present disclosure is not limited thereto. In an embodiment, the thickness T1 may be a thickness, in the third direction D3, between the fourth side 100_d and a topmost level of the third side 100_c, and the thickness T2 may be a thickness, in the third direction D3, between the topmost level of the third side 100_c and an upper surface of the protective film structure 110.

Since the protective film structure 110 covers the third side 100_c of the semiconductor chip, further formation of cracks that may occur in the semiconductor chip 100 may be prevented. The problem of reduced reliability that may be caused by additional cracks may be reduced.

The protective film structure 110 may include, for example, copper (Cu), but the embodiment of the present disclosure is not limited thereto. As another example, the protective film structure 110 may include gold (Au). Because the material included in the protective film structure 110 has a higher thermal conductivity than the material included in the semiconductor chip 100, the heat generated in the semiconductor chip 100 may be more easily released. For example, the semiconductor chip 100 may include silicon (Si), and the protective film structure 110 may include copper (Cu). In this case, the thermal conductivity of the protective film structure 110 may be higher than that of the semiconductor chip 100. Due to the presence of the protective film structure 110, the heat of the upper part of the semiconductor chip 100 may be more easily released. Therefore, the problem of reduced reliability that may occur due to the heat generation may decrease.

The first chip pads 111 and the second chip pads 112 may be provided on the lower side of the semiconductor chip 100. The fourth side 100_d of the semiconductor chip may be disposed to face the first side 300L_a of the lower redistribution substrate. The first chip pads 111 of the semiconductor chip 100 may be connected to the third lower redistribution pattern RDL_L3. The second chip pads 112 may be connected to the third lower redistribution pattern RDL_L3.

The second connecting members 150 may be disposed between the first chip pads 111 of the semiconductor chip 100 and the second chip pads 112. The second connecting members 150 may be attached to the first chip pads 111 and the second chip pads 112. The semiconductor chip 100 and the solder balls SB may be electrically connected through the second connecting members 150.

The second connecting members 150 may be, but not limited to, a solder bump including a low-melting point metal, for example, tin (Sn) or a tin (Sn) alloy such as. The second connecting members 150 may have various shapes, such as a land, a ball, a pin, and a pillar. The second connecting members 150 may be formed of a single layer or multiple layers. When the second connecting members 150 are formed of a single layer, the second connecting members 150 may include tin-silver (Sn—Ag) solder or copper (Cu). When the second connecting members 150 are formed of multiple layers, the second connecting members 150 may include copper (Cu) filler and solder, as an example. The number, interval, or placement of the second connecting members 150 are not limited to those shown in the drawings and may be various depending on the design.

The metal pillars 360 may be provided around the semiconductor chip 100. The metal pillars 360 may electrically connect the lower redistribution substrate 300L and the upper redistribution substrate 300U with each other. The metal pillars 360 may penetrate the molding film 370. The upper side of the metal pillars 360 may be coplanar with the upper side of the molding film 370. The lower side of the metal pillars 360 may contact the third lower redistribution patterns RDL_L3 of the lower redistribution substrate 300L.

The molding film 370 may be provided between the lower redistribution substrate 300L and the upper redistribution substrate 300U. The molding film 370 may cover the semiconductor chip 100. For example, the molding film 370 may cover the fourth side 100_d of the semiconductor chip. The molding film 370 may be provided on the first side 300L_a of the lower redistribution substrate. The molding film 370 may cover the side wall and the upper side of the semiconductor chip 100. The molding film 370 may fill the gap between the metal pillars 360. The thickness, in the third direction D3, of the molding film 370 may be substantially the same as the thickness, in the third direction D3, of the metal pillar 360. The molding film 370 may include an insulating polymer such as an epoxy-based molding compound.

The upper redistribution substrate 300U may include first to third upper insulating layers 310U, 320U, and 330U, and upper redistribution patterns RDL_U inside the first to third upper insulating layers 310U, 320U, and 330U. The first to third upper insulating layers 310U, 320U, and 330U may include the same material as the material included in the first to third lower insulating layers 310L, 320L, and 330L.

For example, each of the first to third upper insulating layers 310U, 320U, and 330U may be made up of a photoimageable dielectric. The first to third upper insulating layers 310U, 320U, and 330U may include a photosensitive polymer. The photosensitive polymer may be formed of at least one of, for example, photosensitive polyimide, polybenzoxazole, phenol-based polymer, and benzocyclobutene-based polymer. As another example, the first to third upper insulating layers 310U, 320U, and 330U may be formed of a silicon oxide film, a silicon nitride film, or a silicon oxynitride film.

The upper redistribution patterns RDL_U may include the same material as the first to third lower redistribution patterns RDL_L1, RDL_L2, and RDL_L3. For example, the upper redistribution patterns RDL_U may include, but not limited to, copper (Cu). In an embodiment, the upper redistribution patterns RDL_U may include a diffusion barrier to prevent Cu diffusion.

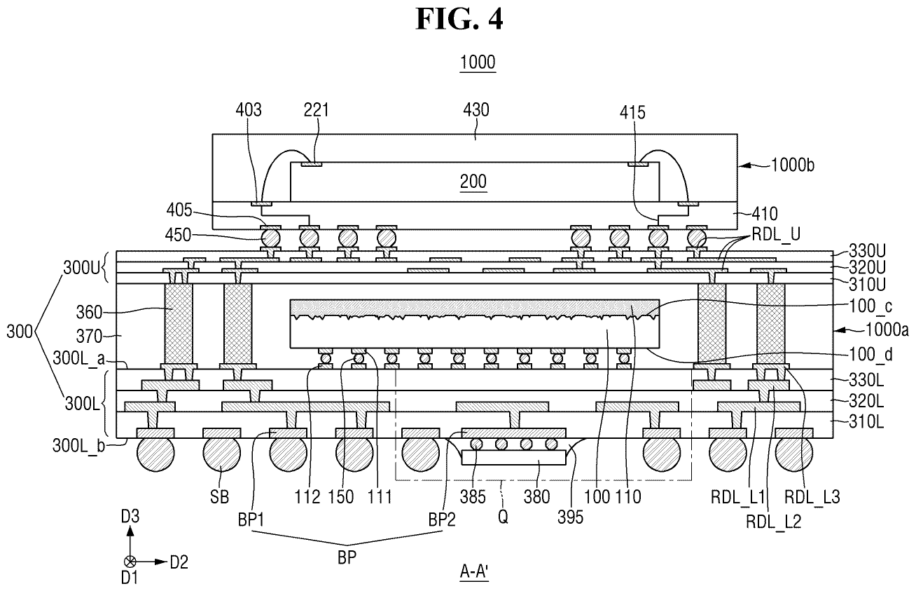

FIG. 4 is an example cross-sectional view taken along line A-A of FIG. 1 according to another embodiment of the present disclosure. For convenience of explanation, FIG. 4 will mainly describe differences from those described in FIGS. 1 to 3.

Referring to FIG. 4, the semiconductor package 1000 according to another embodiment of the present disclosure may further include a second semiconductor package 1000b and a plurality of third connecting members 450.

The second semiconductor package 1000b may include a circuit board 410, a second semiconductor chip 200, and an upper molding film 430. The circuit board 410 may be, but not limited to, a printed circuit board. A plurality of the lower conductive pads 405 may be disposed on the lower side of the circuit board 410.

The second semiconductor chip 200 may be disposed on the circuit board 410. The second semiconductor chip 200 may include integrated circuits. The integrated circuits may include a memory circuit, a logic circuit, or a combination thereof. A plurality of the second chip pads 221 of the second semiconductor chip 200 may be electrically connected to a plurality of upper conductive pads 403 on the upper side of the circuit board 410 by wire bonding. The upper conductive pads 403 on the upper side of the circuit board 410 may be electrically connected to the lower conductive pads 405 through an internal wiring 415 inside the circuit board 410.

The upper molding film 430 may be provided on the circuit board 410. The upper molding film 430 may cover the second semiconductor chip 200. The upper molding film 430 may include an insulating polymer, such as an epoxy-based polymer.

A plurality of third connecting members 450 may be provided between the lower conductive pads 405 of the circuit board 410 and the upper redistribution patterns RLD_U. The third connecting members 450 may be, but not limited to, solder bumps including a low-melting point metal, for example, tin (Sn) or a tin (Sn) alloy. The third connecting members 450 may have various shapes, such as a land, a ball, a pin, and a pillar. The third connecting members 450 may be formed of a single layer or multiple layers. When the third connecting members 450 are formed of a single layer, the third connecting members 450 may include tin-silver (Sn—Ag) solder or copper (Cu), as an example. When the third connecting members 450 are formed of multiple layers, the third connecting members 450 may include copper (Cu) filler and solder, as an example. The number, intervals, or placement of the third connecting members 450 are not limited to those shown in the drawings, and may be various depending on the design.

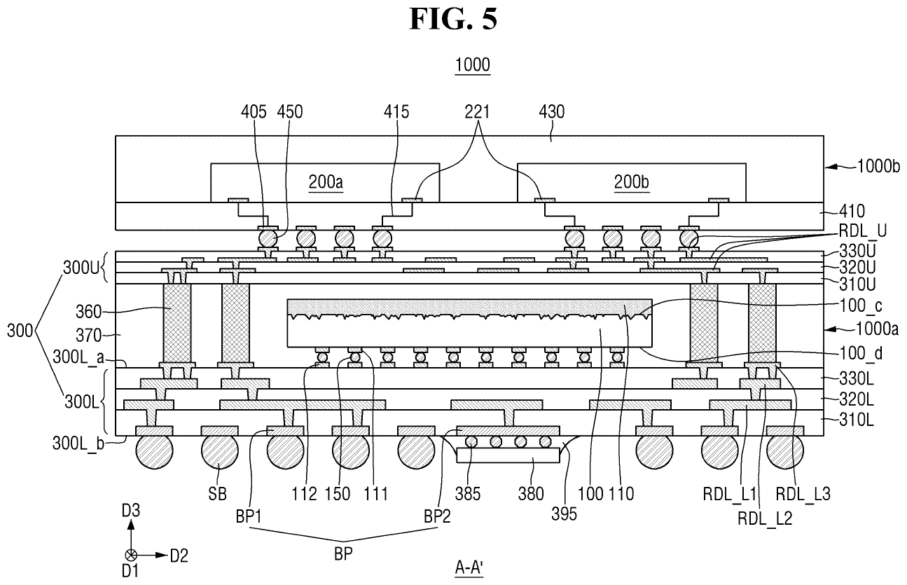

FIG. 5 is an example cross-sectional view taken along line A-A of FIG. 1 according to another embodiment of the present disclosure. For convenience of explanation, FIG. 5 will mainly describe differences from those described in FIGS. 1 to 3.

Referring to FIG. 5, a second semiconductor package 1000b according to another embodiment of the present disclosure may include two second semiconductor chips 200a and 200b. For example, the second semiconductor package 1000b may include a first semiconductor chip 200a and a second semiconductor chip 200b.

The first semiconductor chip 200a and the second semiconductor chip 200b may be spaced apart from each other in the second direction D2. The first semiconductor chip 200a and the second semiconductor chip 200b may be separated from each other by an upper molding film 430. Each of the first semiconductor chip 200a and the second semiconductor chip 200b may include second chip pads 221 at its lower side. The second semiconductor package 1000b does not include an upper conductive pad 403 as shown in FIG. 4. As an example, the second chip pads 221 may be electrically connected to the lower conductive pad 405 through an internal wiring 415 inside the circuit board 410.

Although the first and second semiconductor chips 200a and 200b are shown to be disposed on the upper side of the circuit board 410 at the same level, the embodiment of the present disclosure is not limited thereto. As another example, the first semiconductor chip 200a and the second semiconductor chip 200b may be sequentially stacked on the upper side of the circuit board 410 in the third direction D3.

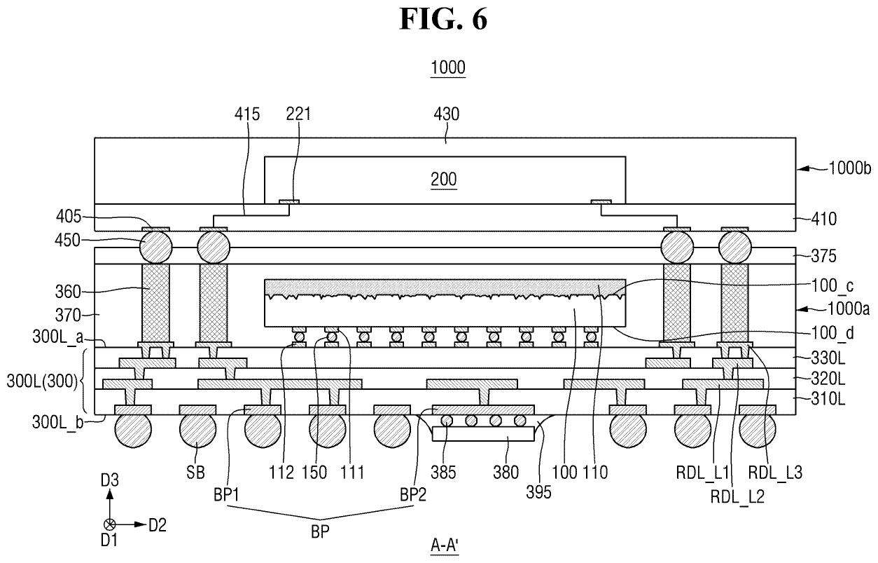

FIG. 6 is an example cross-sectional view taken along line A-A in FIG. 1 according to another embodiment of the present disclosure. For convenience of explanation, FIG. 6 will mainly describe differences from those described in FIGS. 1 to 3.

Referring to FIG. 6, the first semiconductor package 1000a according to another embodiment of the present disclosure may not include the upper redistribution substrate 300U as shown in FIG. 2. For example, the upper redistribution substrate 300U may be omitted from the first semiconductor package 1000a according to another embodiment of the present disclosure.

In an embodiment, an upper insulating layer 375 may be provided on the molding film 370. The upper insulating layer 375 may include an insulating material. For example, the upper insulating layer 375 may include, but not limited to, at least one of silicon oxide, silicon nitride, silicon oxynitride, and a low dielectric constant (low-k) material having a dielectric constant lower than that of silicon oxide.

The third connecting members 450 may be provided between the lower conductive pads 405 of the circuit board 410 and the metal pillars 360 of the first semiconductor package 1000a. Some of the third connecting members 450 may be disposed in the upper insulating layer 375. One sides of the third connecting members 450 may be connected to the lower conductive pads 405, and the other sides of the third connecting members 450 may be connected to the metal pillars 360. Accordingly, the first semiconductor package 1000a and the second semiconductor package 1000b may be electrically connected using the third connecting members 450.

The second semiconductor chip 200 may be disposed on the circuit board 410. The second chip pads 221 of the second semiconductor chip 200 may abut on the upper side of the circuit board 410. The second chip pads 221 of the second semiconductor chip 200 may be electrically connected to the lower conductive pads 405 through the internal wiring 415 in the circuit board 410.

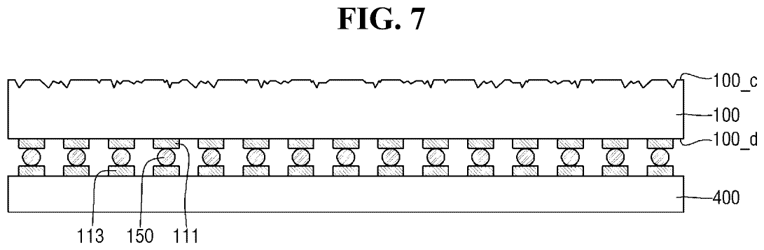

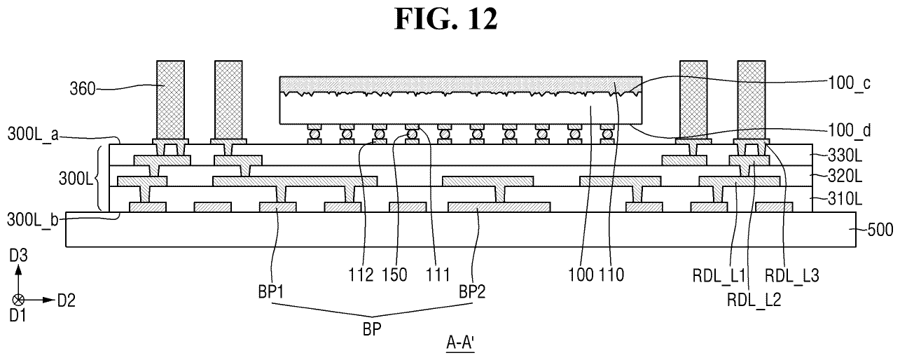

FIGS. 7 to 17 are diagrams for explaining the manufacturing process of the semiconductor package having the cross-section of FIG. 2. For reference, FIGS. 7 to 11 are diagrams showing the manufacturing process of the semiconductor chip according to some embodiments of the present disclosure, and FIGS. 12 to 17 are diagrams showing the manufacturing process of the semiconductor package including the semiconductor chip according to some embodiments of the present disclosure.

Referring to FIG. 7, the semiconductor chip 100 may be provided on a first carrier substrate 400. The semiconductor chip 100 may include a third side 100_c (i.e., an upper surface) and a fourth side 100_d (i.e., a lower surface) that are opposite to each other. The third side 100_c of the semiconductor chip has an uneven surface. For example, the third side 100_c of the semiconductor chip may include unevenness disposed irregularly. For example, the third side 100_c of the semiconductor chip 100 may include surface irregularities that are distributed in a non-uniform manner.

The fourth side 100_d of the semiconductor chip may be disposed to face the first carrier substrate 400. For example, the fourth side 100_d of the semiconductor chip may be adjacent to the first carrier substrate 400. The first chip pads 111, the second connecting members 150, and the third chip pads 113 may be disposed between the first carrier substrate 400 and the semiconductor chip 100. For example, the semiconductor chip 100 may be fixed to the first carrier substrate 400 by the first chip pads 111, the second connecting members 150, and the third chip pads 113.

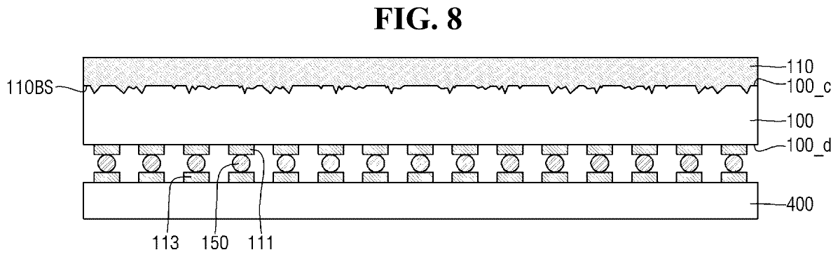

Next, referring to FIG. 8, a protective film structure 110 may be formed on the third side 100_c of the semiconductor chip. The protective film structure 110 may be formed by, for example, but not limited to, a physical vapor deposition (PHD) method.

The protective film structure 110 may be formed on the unevenness formed on the third side 100_c of the semiconductor chip. In other words, no space may be formed between the protective film structure 110 and the semiconductor chip 100. For example, the protective film structure 110 may contact the third side 100_c of the semiconductor chip. In an embodiment, the protective film structure 110 may include, for example, copper (Cu) or gold (Au). The semiconductor chip 100 that is unpackaged may be subject to a package process of forming a wafer level packaging such as WL-CSP, and thus a silicon substrate of the semiconductor chip 100 may contact the protective film structure 110.

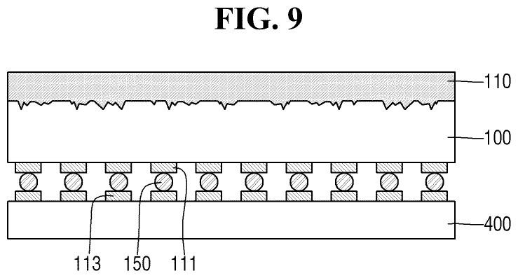

Referring to FIG. 9, a process of cutting the semiconductor chip 100 along a dicing line (not shown) may be performed.

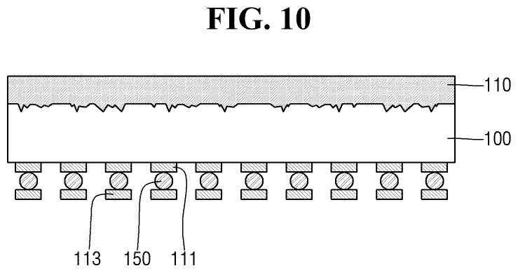

Next, referring to FIG. 10, the first carrier substrate 400 may be removed. The process of removing the first carrier substrate 400 may include, but not limited to, a taping and tape removal process.

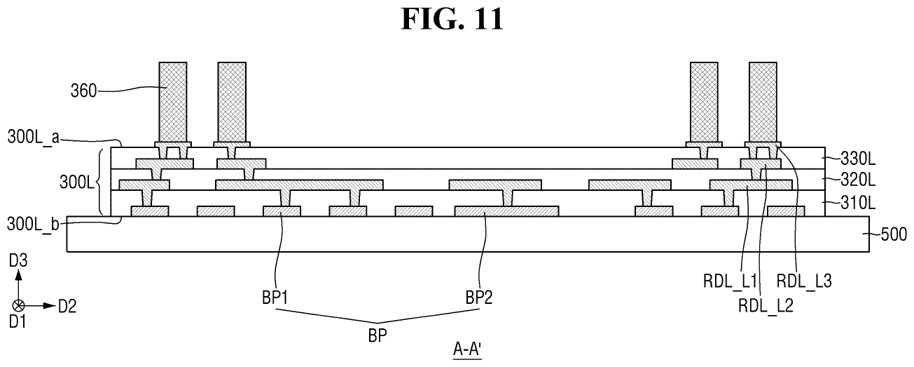

Referring to FIG. 11, the lower redistribution substrate 300L, the first to third lower redistribution patterns RDL_L1, RDL_L2, and RDL_L3, and the metal pillars 360 may be formed.

First, the first lower insulating layer 310L may be formed. A via portion of the first lower redistribution pattern RDL_L1 may be formed in the first lower insulating layer 310L. Next, the second lower insulating layer 320L may be formed. A wiring portion of the first lower redistribution pattern RDL_L1 and a via portion of the second lower redistribution pattern RDL_L2 may be formed in the second lower insulating layer 320L. Next, the third lower insulating layer 330L may be formed. A wiring portion of the second lower redistribution pattern RDL_L2 and a via portion of the third lower redistribution pattern RDL_L3 may be formed in the third lower insulating layer 330L. A wiring portion of the third lower redistribution pattern RDL_L3 may be formed on the third lower insulating layer 330L.

The lower redistribution substrate 300L includes first to third lower insulating layers 310L, 320L, and 330L. The lower redistribution substrate 300L includes a first side 300L_a (i.e., an upper surface) and a second side 300L_b (i.e., a lower surface) that are opposite to each other in a third direction D3. The first side 300L_a of the lower redistribution substrate may be the upper side of the third lower insulating layer 330L. The second side 300L_b of the lower redistribution substrate may be the lower side of the first lower insulating layer 310L. Metal pillars 360 may be formed on the first side 300L_a of the lower redistribution substrate. In an embodiment, the metal pillars 360 may include copper, tungsten, or aluminum. Each metal pillar may be surrounded by a diffusion barrier including titanium (Ti), titanium nitride (TiN), tantalum (Ta), or tantalum nitride (TaN) to prevent Cu diffusion and ensure adhesion to a dielectric layer such as the molding film 370, which is formed later.

Referring to FIG. 12, the semiconductor chip 100 may be mounted on the first side 300L_a of the lower redistribution substrate. For reference, the semiconductor chip 100 mounted in FIG. 12 is the semiconductor chip 100 formed by the processes of FIGS. 7 to 10. The protective film structure 110 may be disposed on the upper side of the semiconductor chip 100 mounted on the first side 300L_a of the lower redistribution substrate.

First, the second connecting members 150 may be landed on the third lower redistribution pattern RDL_L3. Next, the first semiconductor chip 100 may be mounted on the second connecting members 150. The first chip pads 111 may be connected to the second connecting members 150.

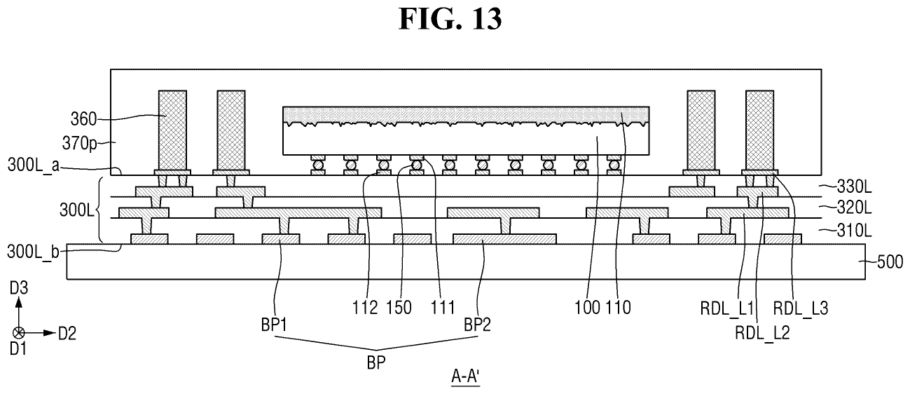

Next, referring to FIG. 13, a preliminary molding film 370p may be formed. The preliminary molding film 370p may cover the first semiconductor chip 100 and the metal pillars 360.

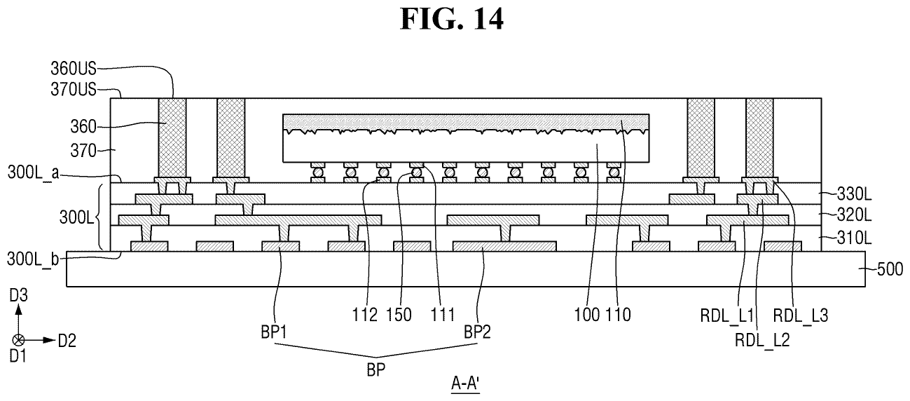

Referring to FIG. 14, the upper side 370US of the molding film 370 and the upper side 360US of the metal pillars 360 may be disposed on the same plane by a grinding process. In an embodiment, the preliminary molding film 370p may be partially removed by using a planarization process such as a chemical-mechanical planarization (CMP) process to form the molding film 370. The planarization process may be performed such that the upper side 370US of the molding film 370 may be coplanar with the upper side 360US of the metal pillars 360.

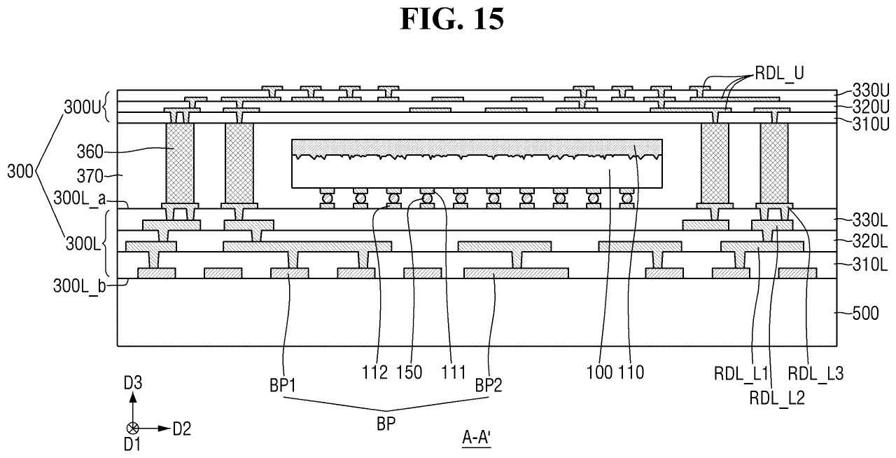

Referring to FIG. 15, the upper redistribution substrate 300U may be formed on the molding film 370. The upper redistribution substrate 300U may include first to third upper insulating layers 310U, 320U, and 330U. The upper redistribution patterns RDL_U may be formed in the first to third upper insulating layers 310U, 320U, and 330U.

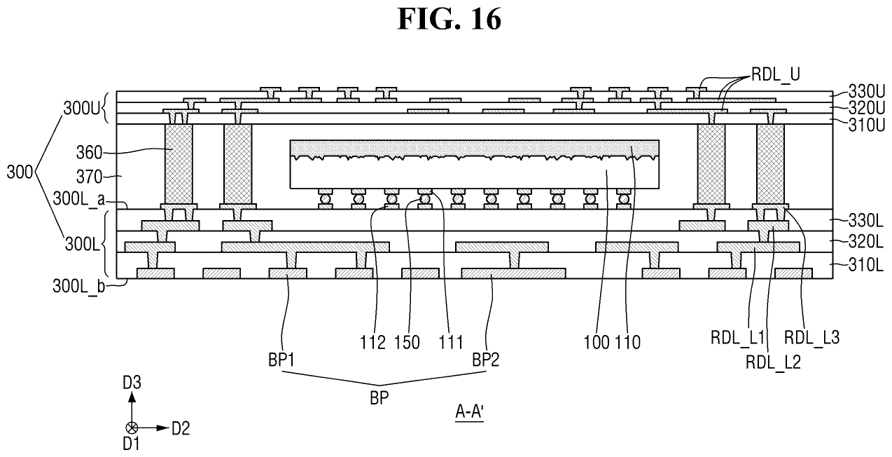

Next, referring to FIG. 16, the second carrier substrate (see 500 of FIG. 15) may be removed. The carrier substrate 500 is removed, and the second side 300L_b of the lower redistribution substrate is exposed. The process of removing the second carrier substrate 500 may include, but not limited to, a taping and tape removal process.

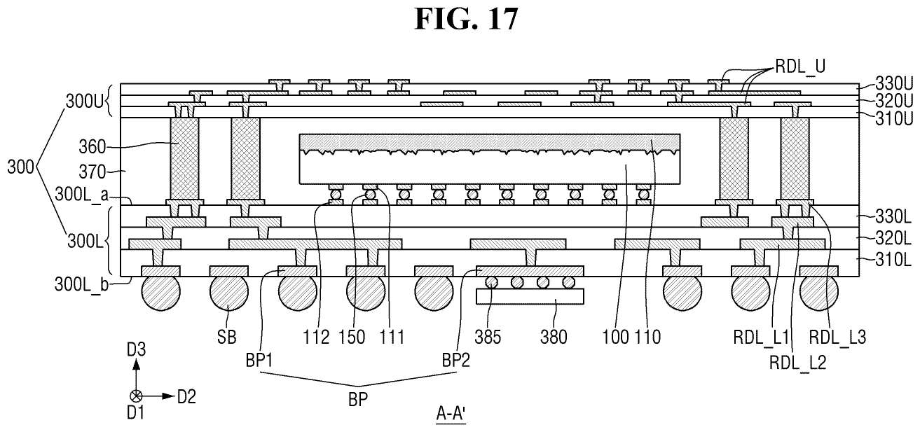

Referring to FIG. 17, a plurality of solder balls SB and a plurality of first connecting members 385 may be landed on the second side 300L_b of the lower redistribution substrate. The solder balls SB may be connected to the first ball pad BP1. The plurality of first connecting members 385 may be connected to the second ball pad BP2 which are expose at the second side 300L_b of the lower redistribution substrate. The silicon capacitor 380 may be mounted on the first connecting members 385.

Next, referring to FIG. 2, an underfill 395 may be discharged. The underfill 395 is discharged to the second side 300L_b of the lower redistribution substrate, and may flow into the space between the silicon capacitor 380 and the lower redistribution substrate 300L. The underfill 395 may fill the space between the silicon capacitor 380 and the lower redistribution substrate 300L.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor package comprising:
a first redistribution substrate which includes an upper surface and a lower surface that are opposite to each other in a vertical direction perpendicular to the upper surface;
a semiconductor chip which is mounted on the upper surface of the first redistribution substrate, and includes an upper surface and a lower surface that are opposite to each other in the vertical direction;
a protective film structure disposed on the upper surface of the semiconductor chip;
a silicon capacitor disposed on the lower surface of the first redistribution substrate;
an encapsulant which covers the upper surface of the first redistribution substrate, a side surface of the semiconductor chip, and the protective film structure; and
a plurality of solder balls disposed on the lower surface of the first redistribution substrate,
wherein the plurality of solder balls are arranged to surround the silicon capacitor when viewed in a plan view, and
wherein the lower surface of the semiconductor chip is adjacent to the upper surface of the first redistribution substrate.

2. The semiconductor package of claim 1,
wherein the upper surface of the semiconductor chip is entirely covered with the protective film structure.

3. The semiconductor package of claim 1,
wherein the upper surface of the semiconductor chip includes surface irregularities that are distributed in a non-uniform manner.

4. The semiconductor package of claim 1,
wherein a thickness, in the vertical direction, of the protective film structure has a value in a range of 3 μm to 10 μm, inclusive.

5. The semiconductor package of claim 1,
wherein a thickness, in the vertical direction, between an upper surface of the protective film structure and a topmost level of the upper surface of the semiconductor chip has a value in a range of 2% to 10%, inclusive, of a thickness, in the vertical direction, between the lower surface of the semiconductor chip to the topmost level of the upper surface of the semiconductor chip.

6. The semiconductor package of claim 1,
wherein the protective film structure includes at least one of copper (Cu) and gold (Au).

7. The semiconductor package of claim 1, further comprising:
a plurality of connecting members disposed in a space between the silicon capacitor and the first redistribution substrate; and
an underfill which covers the plurality of connecting members disposed in the space between the silicon capacitor and the first redistribution substrate.

8. The semiconductor package of claim 7, further comprising:
a second redistribution substrate disposed on the upper surface of the semiconductor chip; and
a plurality of metal pillars penetrating the encapsulant and connecting the second redistribution substrate to the first redistribution substrate,
wherein the plurality of connecting members are electrically connected to the second redistribution substrate through the plurality of metal pillars.

9. The semiconductor package of claim 7,
wherein the plurality of connecting members include copper (Cu).

10. A semiconductor package comprising:
a first redistribution substrate which includes an upper surface and a lower surface that are opposite to each other in a vertical direction perpendicular to the upper surface;
a semiconductor chip which is mounted on the upper surface of the first redistribution substrate, and includes an upper surface and a lower surface that are opposite to each other in the vertical direction;
a protective film structure disposed on the upper surface of the semiconductor chip;
a plurality of connecting members which are disposed in a space between the upper surface of the first redistribution substrate and the lower surface of the semiconductor chip, and connect the first redistribution substrate to the semiconductor chip;
a second redistribution substrate disposed on the upper surface of the semiconductor chip;
an encapsulant which is disposed in a space between the first redistribution substrate and the second redistribution substrate, and covers the upper surface of the semiconductor chip and the upper surface of the first redistribution substrate;
a plurality of metal pillars penetrating the encapsulant and connecting the first redistribution substrate to the second redistribution substrate; and
a plurality of solder balls which are disposed on the lower surface of the first redistribution substrate.

11. The semiconductor package of claim 10,
wherein the lower surface of the semiconductor chip is adjacent to the upper surface of the first redistribution substrate.

12. The semiconductor package of claim 10, further comprising:
a silicon capacitor disposed on the lower surface of the first redistribution substrate,
wherein the plurality of solder balls are arranged to surround the silicon capacitor when viewed in a plan view.

13. The semiconductor package of claim 12,
wherein the silicon capacitor has a square shape when viewed in a plan view.

14. The semiconductor package of claim 10,
wherein the upper surface of the semiconductor chip includes surface irregularities that are distributed in a non-uniform manner.

15. The semiconductor package of claim 10,
wherein a thickness, in the vertical direction, of the protective film structure has a value in a range of 3 μm to 10 μm, inclusive.

16. The semiconductor package of claim 10,
wherein a thickness, in the vertical direction, between an upper surface of the protective film structure and a topmost level of the upper surface of the semiconductor chip has a value in a range of 2% to 10%, inclusive, of a thickness, in the vertical direction, between the lower surface of the semiconductor chip to the topmost level of the upper surface of the semiconductor chip.

17. The semiconductor package of claim 10,
wherein the protective film structure includes at least one of copper (Cu) and gold (Au).

18. A semiconductor package comprising:
a first redistribution substrate which includes an upper surface and a lower surface that are opposite to each other in a vertical direction perpendicular to the upper surface;
a semiconductor chip which is mounted on the upper surface of the first redistribution substrate, and includes an upper surface and a lower surface that are opposite to each other in the vertical direction;
a protective film structure disposed on the upper surface of the semiconductor chip;
a silicon capacitor which is disposed on the lower surface of the first redistribution substrate and has a square shape when viewed in a plan view;
a plurality of connecting members disposed in a space between the silicon capacitor and the first redistribution substrate;
an underfill which covers the plurality of connecting members disposed in the space between the silicon capacitor and the first redistribution substrate; and
a plurality of solder balls which are arranged to surround the silicon capacitor when viewed in the plan view, and are disposed on the lower surface of the first redistribution substrate,
wherein the upper surface of the semiconductor chip includes surface irregularities that are distributed in a non-uniform manner, and
wherein a thickness, in the vertical direction, between an upper surface of the protective film structure and a topmost level of the upper surface of the semiconductor chip has a value in a range of 2% to 10%, inclusive, of a thickness, in the vertical direction, between the lower surface of the semiconductor chip to the topmost level of the upper surface of the semiconductor chip.

19. The semiconductor package of claim 18, wherein a thickness, in the vertical direction, of the protective film structure has a value in a range of 3 μm to 10 μm, inclusive.

20. The semiconductor package of claim 18,
wherein the protective film structure includes at least one of copper (Cu) and gold (Au).
